(19) United States
(12) Patent Application Publication
(10) Pub. No.: US 2023/0235644 A1
(43) Pub. Date: Jul. 27, 2023

(54) WELL TESTING OPERATIONS USING AUTOMATED CHOKE CONTROL

(71) Applicant: Halliburton Energy Services, Inc., Houston, TX (US)

(72) Inventors: Adam Harold Martin, Carrollton, TX (US); Daniel Joshua Stark, Carrollton, TX (US); Mark McGouldrick, Arbroath (GB)

(21) Appl. No.: 17/584,095

(22) Filed: Jan. 25, 2022

(51) Int. Cl. E21B 34/08; E21B 44/00; E21B 47/10

(52) U.S. Cl. CPC E21B 34/08; E21B 44/00; E21B 47/10; E21B 2200/02; E21B 2200/20; E21B 2200/22

(57) ABSTRACT

The disclosure presents processes to improve the calibration of adjustable choke valves corresponding to a specific size of positive choke bean. Typically, manufacturers specify a position of the adjustable choke valve that corresponds to a specific choke bean size. Hydrocarbon fluid conditions and composition vary and subterranean formation characteristics vary which can lead to errors in the calibration. By comparing flow rate parameters of the hydrocarbon fluid flowing through the adjustable choke manifold and the positive choke manifold, errors in calibration can be detected and corrected. The factors involved with the hydrocarbon fluid and the error correction can be used to update a choke model. The choke model can then be used for future calibrations of the adjustable choke valve.

### TECHNICAL FIELD

This application is directed, in general, to well testing operations and, more specifically, to using machine learning to control adjustable choke valves.

### BACKGROUND

When hydrocarbon wells begin production, well testing processes should be conducted to optimize the flow rate of the hydrocarbon fluids. Many factors can be involved in optimizing the flow rate, such as protecting downstream equipment from high pressure, minimizing the possibility of fracture shut-ins or collapse, minimizing solids or contaminants in the hydrocarbon fluids, and other target optimizations. Conventionally, a choke manifold is used to restrict the hydrocarbon fluid flow. The choke manifold can include a positive choke bean. Changing out the choke bean can take time, increase safety issues, and release hydrocarbon emissions to the environment as the positive choke manifold needs to be taken apart to change the choke bean. Some choke manifolds include an adjustable choke valve. Due to the physical attributes of the adjustable choke valve, the composition and attributes of the hydrocarbon fluids, and regional or subterranean formation characteristics, the calibration between the positive choke bean and the adjustable choke valve may not be accurate. It would be beneficial to improve the calibration allowing a future state where the positive choke manifold portion can be removed from the system.

### SUMMARY

In one aspect, a method to reduce a calibration error for an adjustable choke valve of a choke manifold at a well site is disclosed. In one embodiment, the method includes (1) analyzing a hydrocarbon fluid flowing through a positive choke manifold portion of the choke manifold to generate a first flow state, wherein an adjustable choke manifold portion of the choke manifold is isolated to direct the hydrocarbon fluid to the positive choke manifold portion, the positive choke manifold portion utilizes a choke bean of an equivalent size to a choke size in a set of designated choke sizes, and the hydrocarbon fluid is flowing from a wellbore at the well site, (2) analyzing a hydrocarbon fluid flowing through the adjustable choke manifold portion utilizing input parameters to generate a second flow state, and the adjustable choke manifold portion has an adjustable choke position for the adjustable choke valve, where the adjustable choke position is equivalent to the choke size, and (3) adjusting the adjustable choke position to compensate for a first margin of error to determine an adjusted choke valve position, wherein the first margin of error is calculated utilizing the first flow state and the second flow state.

In a second aspect, a system is disclosed. In one embodiment, the system includes (1) a choke manifold having one or more adjustable choke valves, and capable of isolating each fluid flow path of the choke manifold, where the choke manifold is located at a well site of a hydrocarbon fluid producing wellbore, and (2) a choke model processor capable to receive collected data and generate a recommended position for the one or more adjustable choke valves using an equivalency of a choke size and the collected data.

In a third aspect, a computer program product having a series of operating instructions stored on a non-transitory computer-readable medium that directs a data processing apparatus when executed thereby to perform operations to reduce a calibration error for an adjustable choke valve of a choke manifold at a well site is disclosed. In one embodiment, the operations include (1) analyzing a hydrocarbon fluid flowing through a positive choke manifold portion of the choke manifold to generate a first flow state, wherein an adjustable choke manifold portion of the choke manifold is isolated to direct the hydrocarbon fluid to the positive choke manifold portion, the positive choke manifold portion utilizes a choke bean of an equivalent size to a choke size in a set of designated choke sizes, and the hydrocarbon fluid is flowing from a wellbore at the well site, (2) analyzing a hydrocarbon fluid flowing through the adjustable choke manifold portion utilizing input parameters to generate a second flow state, and the adjustable choke manifold portion has an adjustable choke position for the adjustable choke valve, where the adjustable choke position is equivalent to the choke size, and (3) adjusting the adjustable choke position to compensate for a first margin of error to determine an adjusted choke valve position, wherein the first margin of error is calculated utilizing the first flow state and the second flow state.

### BRIEF DESCRIPTION

Reference is now made to the following descriptions taken in conjunction with the accompanying drawings, in which:

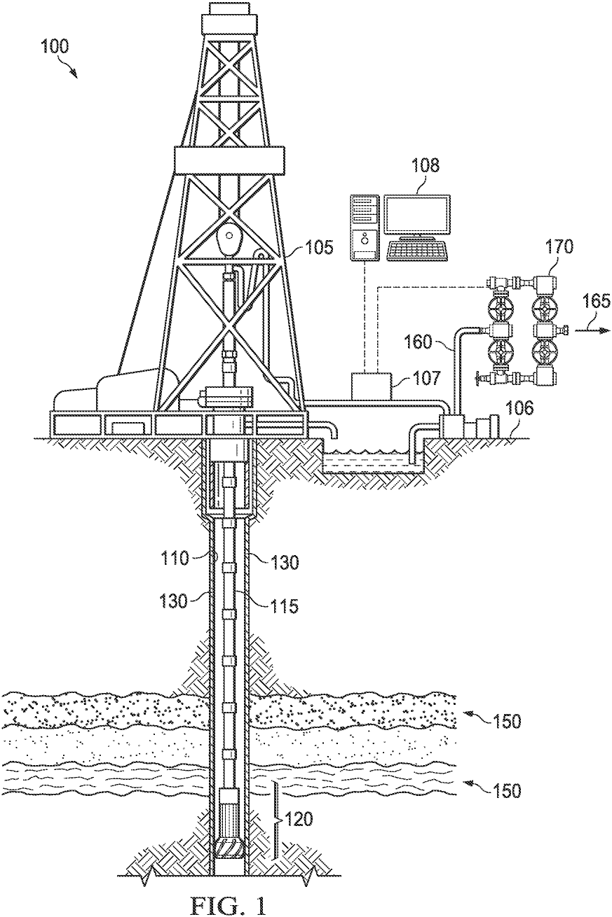

FIG. 1 is an illustration of a diagram of an example hydrocarbon production system;

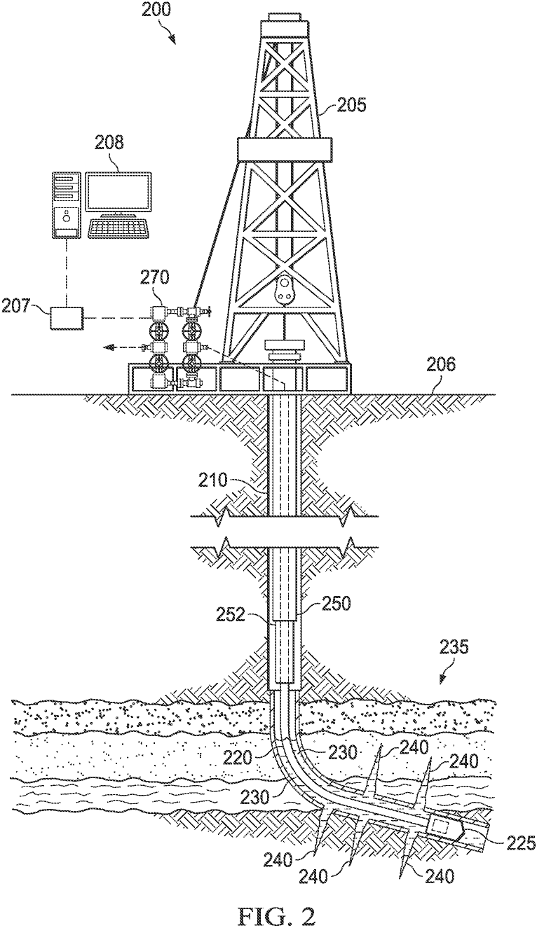

FIG. 2 is an illustration of a diagram of an example hydraulic fracturing system;

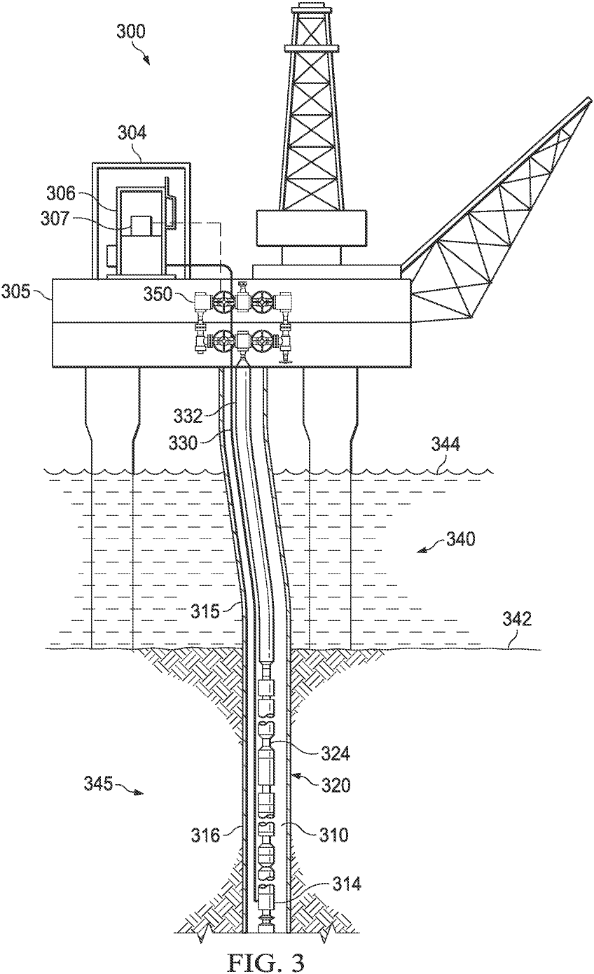

FIG. 3 is an illustration of a diagram of an example offshore hydrocarbon production system;

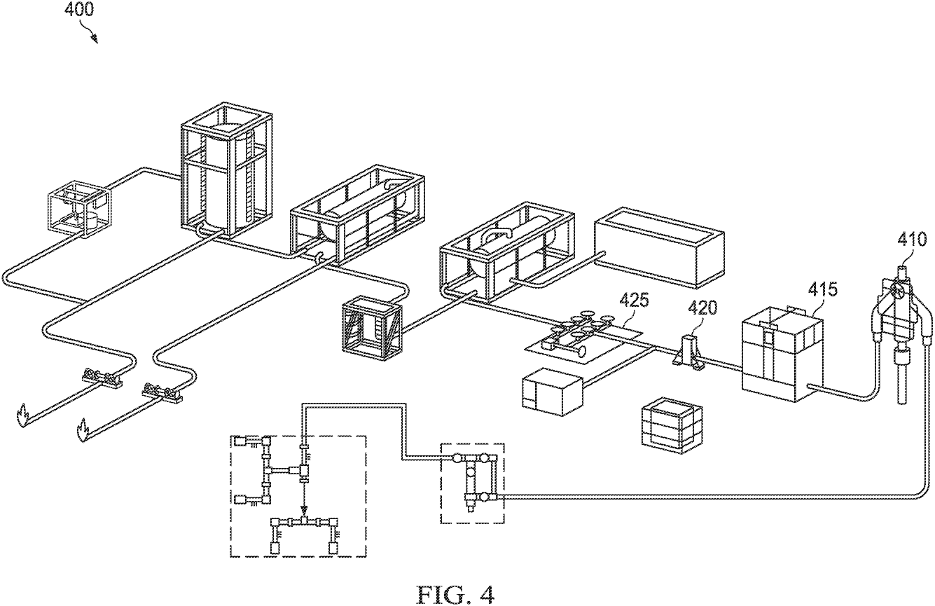

FIG. 4 is an illustration of a diagram of an example well system with a choke manifold;

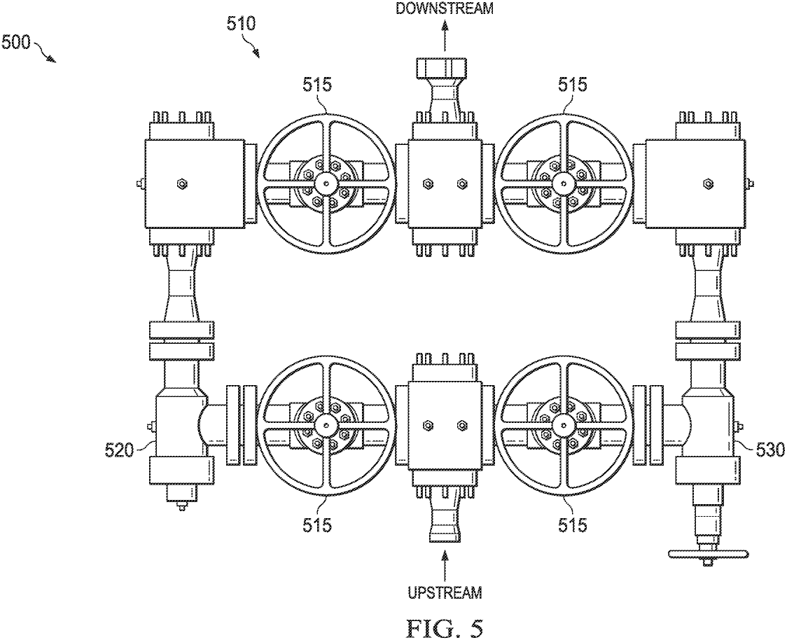

FIG. 5 is an illustration of a diagram of an example choke manifold with a positive choke and an adjustable choke;

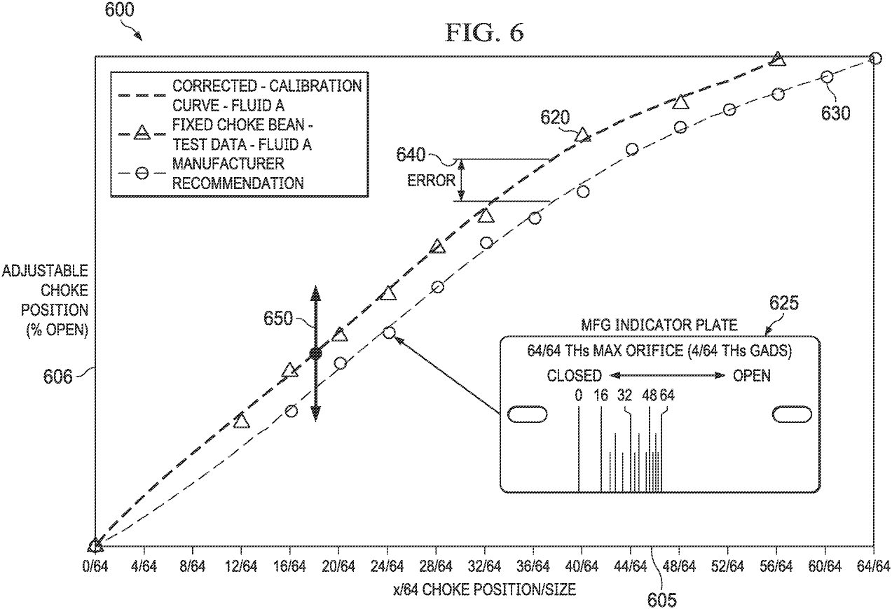

FIG. 6 is an illustration of a diagram of an example chart showing an adjustable choke calibration;

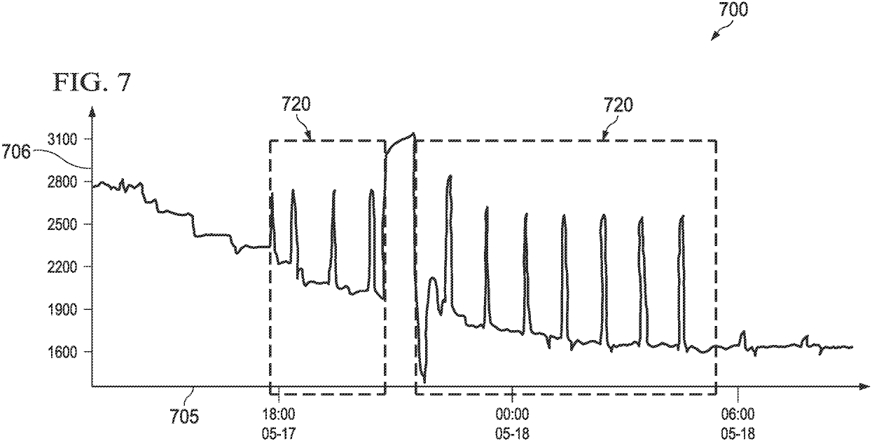

FIG. 7 is an illustration of a diagram of an example chart demonstrating issues during choke changes;

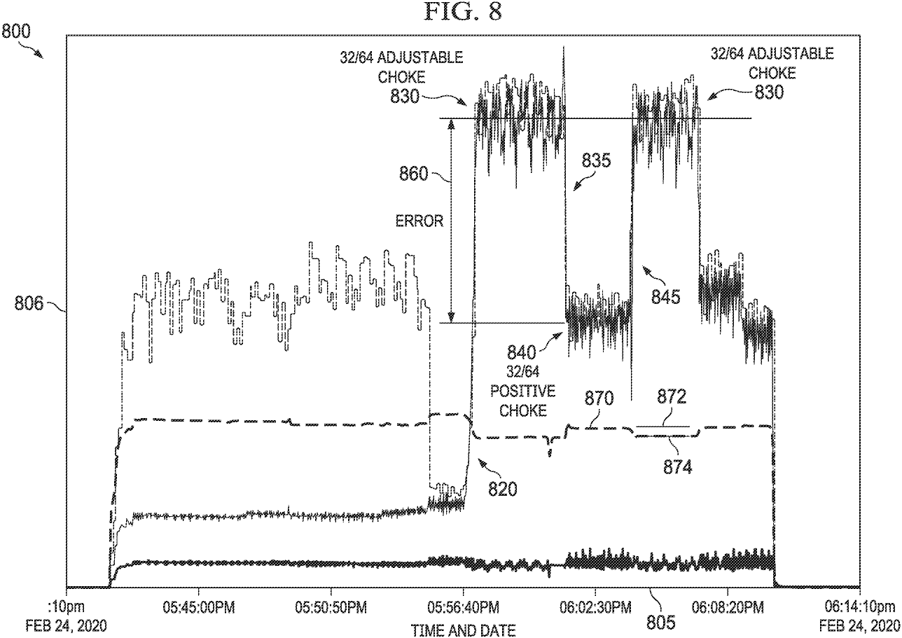

FIG. 8 is an illustration of a diagram of an example chart demonstrating a flow rate margin of error;

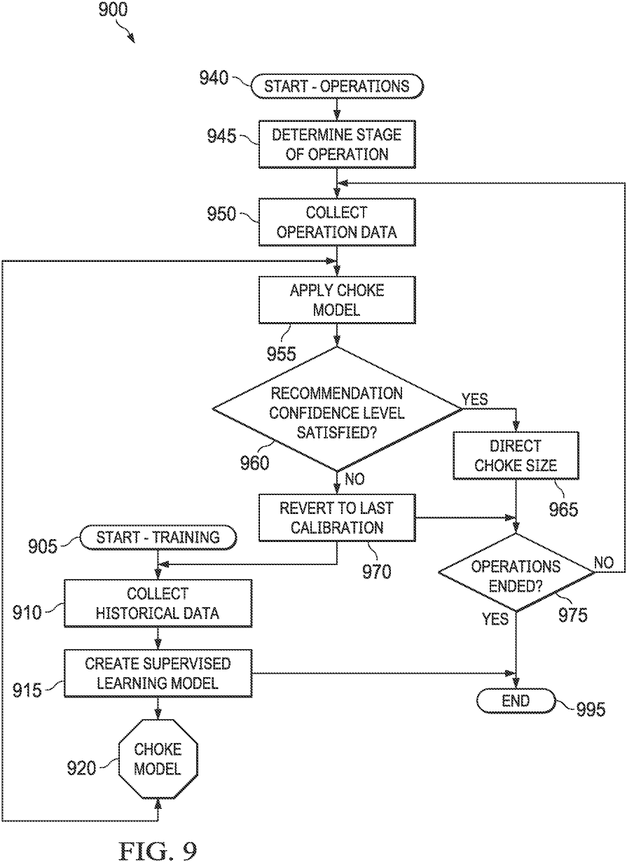

FIG. 9 is an illustration of a flow diagram of an example method to improve and utilize a choke model;

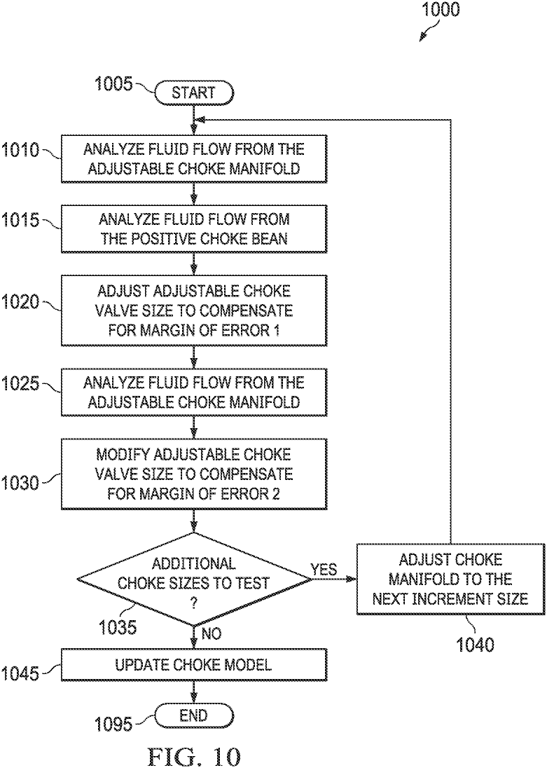

FIG. 10 is an illustration of a flow diagram of an example method to determine a margin of error between a positive choke bean and an adjustable choke valve;

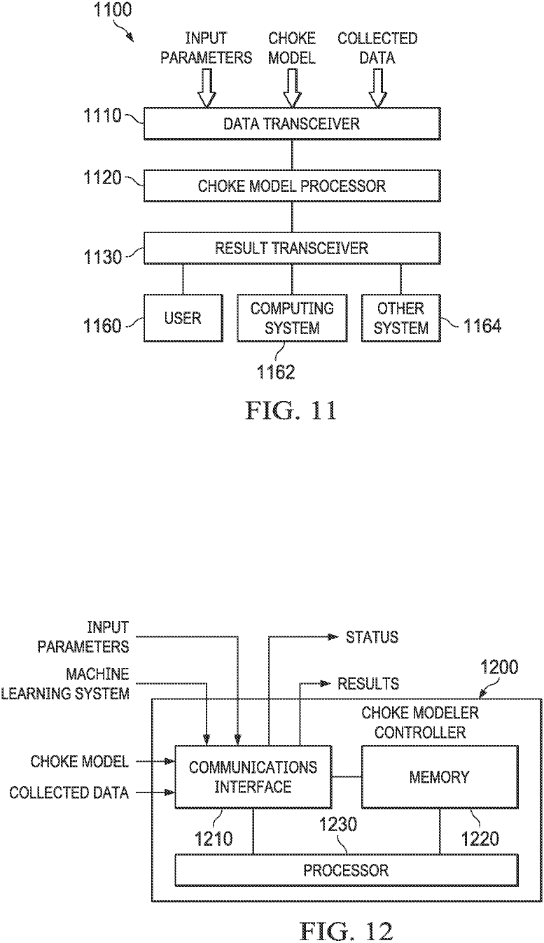

FIG. 11 is an illustration of a block diagram of an example choke model system; and

FIG. 12 is an illustration of a block diagram of an example of a choke model controller according to the principles of the disclosure.

### DETAILED DESCRIPTION

In hydrocarbon production processes, once a wellbore has been developed, i.e., drilled or fractured, such as by hydraulic fracturing (HF), additional operational testing is performed to optimize the wellbore production. A flow rate of the extracted hydrocarbon fluid can be optimized, such as to optimize post HF flowback, e.g., cleanup, to improve overall well production, protect surface equipment, to reduce the presence of contaminants, to provide a consistent environment for collecting data on the hydrocarbon fluids, other factors for flow rate calculations, or a combination of these factors.

The flow rate optimization can take place at various times throughout the wellbore operation plan, for example, at a time the wellbore is completed, or continually or periodically during hydrocarbon extraction process. The flow rate optimization can be part of well testing or flowback operations, that are part of the wellbore operation plan. Well testing operations can take various amounts of time, such as one day, or several months. Well testing can take into account the wellbore, the geologic conditions (such as temperature and pressure), the subterranean formation characteristics, the type of hydrocarbons, the gas to oil ratio (GOR), and other factors.

Well testing can be conducted, in part, using a choke manifold along an extraction pipe. As the hydrocarbons are extracted to the surface, they can proceed through zero or more systems before entering the choke manifold. The choke manifold can reduce the pressure of the hydrocarbons, thereby adjusting the flow rate, and subsequently allow the hydrocarbons to flow to other surface equipment.

Conventionally, choke manifolds utilize a positive choke bean to categorize and quantify hydrocarbon flow using a precise orifice. The choke bean is a standard reference to analyze reservoir performance and hydrocarbon flow, as well as asset reserves. Choke beans can be of various sizes, for example, in 1/64^{th} inch increments.

During a well flowback routine or program, the well can be gradually flowed by choking the well in increments to effectively cleanup the wellbore of contaminates while preventing reservoir or stimulation treatment damage so as to optimize overall well productivity. The goal can be to gradually increase choke size such that a maximum stable flow rate can be achieved prior to well shut-in and subsequent data collection for pressure transient analysis (PTA) reservoir analysis. Determining the maximum stable flow condition can require gradual choke changes, such as changing out the positive choke bean or utilizing an adjustable choke valve.

Conventionally, adjustable choke valve manufactures can calibrate choke position, e.g., size of orifice of the adjustable choke valve, utilizing an equivalent positive choke bean or an equivalent flow area orifice size. The discrepancy with the manufacturers’ calibration can lead to issues and margins of error that are greater than the choke error threshold. Calibration can be fixed e.g., constant calibration, and utilize theoretical or empirical datasets at a constant fluid condition.

Flow rates can vary with fluid property changes, such as pressure changes, temperature changes, density changes, viscosity changes, fluid composition changes, GOR changes, or solids or contaminants in the fluid. The fluid property changes can change over time for a well and from well to well in a reservoir or across reservoirs. Adjustable choke valve flow accuracy can vary depending on the valve design. The variation can often be non-linear.

Current methods of determining the proper choke position during surface well testing requires referencing the adjustable choke fluid flow to the positive choke flow. This comparison can take time and can be corrected manually by human intervention by knowingly adjusting to a position outside of the equivalence scale. These procedures can introduce potential errors when the positive choke bean is changed out for a different sized choke bean. During the well testing process, pressure and flow rate disruptions can occur, as well as an increased potential for poor separation of commercially viable fluids from waste fluids and solids.

In this disclosure, processes are presented to address accuracy discrepancies, e.g., margins of error, of the adjustable choke valve when compared to the corresponding positive choke bean. The processes can provide the benefit of optimizing a stable flow rate and reducing pressure disturbances, e.g., pressure spikes, when switching from the adjustable choke flow to the positive choke flow. A machine learning process, e.g., a machine learning system or a deep learning neural network system, can be used to build a choke model that can be used to automate the orifice size, e.g., position, of the adjustable choke valve to minimize disruption. The machine learning process can be implemented using one or more machine learning methods.

In some aspects, the positive choke bean can be removed from the well testing process and the flow control can be handled by the adjustable choke valve. The choke model can be used to predict adjustable choke sizes depending on the choke model factors, such as GOR, density, viscosity, pressure, temperature, solids content, and other factors. The choke model can be updated using historical data, such as obtained from previous jobs or from lab testing. In some aspects, the choke model can be generated or updated using design of experiments, physics-based techniques, or reliability methodologies. The highest efficiency, e.g., a derivation of highest efficiency, or the highest accuracy, e.g., a derivation of highest accuracy, result can be utilized.

More than one technique can be utilized, such as machine learning, design of experiments, or physics-based techniques, and a statistical algorithm can be utilized to determine the optimal adjustable choke size for the desired step in the well testing. The statistical algorithm can be one of an average, a mean, a median, a maximum, a minimum, a derivation of a highest efficiency, a derivation of a highest accuracy, a Bayesian optimization, an ensemble learning method, a stacked ensemble model, a weighted average, a method of quadrature, such as using penalty functions, a Lagrange multiplier, or a derivative optimization.

In some aspects, the adjustable choke valve position can be determined automatically thereby improving response time and reducing well operation costs. In some aspects, improved efficiency can be achieved for optimizing well cleanup without reservoir damage. In some aspects, the maximum flow stability state can be identified. There can be a reduced time to determine the correct adjustable choke valve position. The adjustable choke valve position can be automatically adjusted as new fluid conditions are encountered, such as using data collected from the fluid currently being received. A target optimization goal can be met using the adjustable choke valve position, such as a maximum hydrocarbon output, a minimized emissions amount, a minimized solids amount, a maximized oil output, a minimized water output, equipment protection, other well production goals, or a combination thereof.

By removing the physical choke bean and the changes to the physical choke bean, emissions can be reduced and safety can be improved, such as the physical choke bean need not be broken, which could reduce the time taken for this operation, such as saving 20 minutes. Reduced hardware requirements can be employed once the physical choke bean is not needed in the well testing process. This can reduce user exposure to high pressures or hazardous gas releases (such as H₂S) during a positive choke bean change.

In some aspects, a physical model of the choke flow can be used to create wider parameter space or used as means to determine physical sensitivities of parameters. For example, additional instrumentation could be fitted to the choke manifold assembly, piping, or choke valve(s) (such as accelerometers, acoustic transmitters, strain gauges, microphones, pressure transmitters, or other devices or sensors) to identify unique fluid signatures indicative of prescribed or impending failure modes. In some aspects, upstream or downstream equipment, (such as solids collection data at a Sand Management System, flow rate data taken at a Separator or Multiphase Flow Meter, density, viscosity, or GOR data taken from one or more downstream equipment, or other well site systems), can provide input data to the machine learning process or choke model. Other examples of the parameters that can be utilized are computational fluid dynamics modeling, finite elemental modeling, analytical derivation from partial or ordinary differential equations, or real-time or near real-time mid-fidelity modeling utilizing graphical processing methods.

In some aspects, a machine learning process can identify choke wear or impending choke failure, such as washout or damage. For example, with the disclosed self-calibrating choke methods (e.g., using choke models, design of experiments, or reliability methodologies), the threshold for the choke position can be determined, e.g., a maximum acceptable error adjustment, such that choke wear can be determined. Fluid velocity detection or measurement methods can aid to operate the choke manifold system in a safe or reliable manner so as to optimize choke longevity or flow control safety.

In some aspects, the target optimization can be minimized emissions, minimized solids, maximized gas output, maximized oil output, minimized water output, maximum flow rate while still laminar, pulsed flow, a balanced combination, and other targets for optimization. In some aspects, machine learning processes can include classification methods or time-series predictive methods. In some aspects, unsupervised learning algorithms, transfer learning methods, or combined modelling methods can be used. In some aspects, proportional integral derivative (PID) control, a fractional order control, a feedforward compensation, a proportional (P) control, a proportional integral (PI) control, a proportional derivative (PD) control, a Proportional Integral Feed Forward (PIFF) control, predictive and fuzzy logic (artificial intelligence or rule based), or other control can be used to maintain an adjustable choke position once the orifice size has been determined using the methods described herein.

Turning now to the figures, FIG. 1 is an illustration of a diagram of an example hydrocarbon production system 100. Hydrocarbon production system 100 includes a derrick 105, a well site controller 107, and a computing system 108. Well site controller 107 can be positioned central to the well site operation or local to the one or more equipment devices (such as the choke manifold) to form a data network among other equipment devices or data transmitters. Well site controller 107 includes a processor and a memory, and is configured to direct operation of hydrocarbon production system 100. Derrick 105 is located at a surface 106.

Extending below derrick 105 is a wellbore 110 with downhole tools 120 at the end of a fluid pipe 115. Downhole tools 120 can include various downhole tools, such as sensors, pumps, and other end of pipe tools. Other components of downhole tools 120 can be present, such as a local power supply (e.g., generators, batteries, or capacitors), telemetry systems, transceivers, and control systems. Wellbore 110 is surrounded by subterranean formation 150.

Well site controller 107 or computing system 108 which can be communicatively coupled to well site controller 107, can be utilized to communicate with downhole tools 120, such as sending and receiving telemetry, data, instructions, subterranean formation measurements, and other information. Computing system 108 can be proximate well site controller 107 or be a distance away, such as in a cloud environment, a data center, a lab, or a corporate office. Computing system 108 can be a laptop, smartphone, PDA, server, desktop computer, cloud computing system, other computing systems, or a combination thereof, that are operable to perform the processes described herein. Well site operators, engineers, and other personnel can send and receive data, instructions, measurements, and other information by various conventional means, now known or later developed, with computing system 108 or well site controller 107. Well site controller 107 or computing system 108 can communicate with downhole tools 120 using conventional means, now known or later developed, to direct operations of downhole tools 120.

Casing 130 can act as barrier between subterranean formation 150 and the fluids and material internal to wellbore 110, as well as fluid pipe 115. The hydrocarbon fluids from subterranean formation 150 enter wellbore 110 and flow to surface 106. The hydrocarbon fluids flow through a pipe 160 to an upstream end of a choke manifold system 170. The downstream end of choke manifold system 170 allows the hydrocarbon fluids to flow through pipe 165 to other surface systems. Choke manifold system 170, or systems further upstream, such as downhole tools 120, can collect data on the hydrocarbon fluids. The collected data can be used to generate a recommendation for a choke valve position, e.g., an adjusted choke valve position, for an adjustable choke manifold system.

FIG. 2 is an illustration of a diagram of an example hydraulic fracturing (HF) well system 200, which can be a well site where HF operations are occurring. HF well system 200 demonstrates a nearly horizontal wellbore.

HF well system 200 includes surface well equipment 205 located at a surface 206, a well site controller 207, and a computing system 208. In some aspects, well site controller 207 is communicatively connected to separate computing system 208, for example, a separate server, data center, cloud service, tablet, laptop, smartphone, edge computing system, or other types of computing systems capable of executing the processes and methods described herein. Computing system 208 can be located proximate to well site controller 207 or located a distance from well site controller 207.

Extending below surface 206 from surface well equipment 205 is a wellbore 210. Wellbore 210 can have zero or more cased sections, such as a cased section 250 and cased section 252, and a bottom section that is uncased. Inserted into wellbore 210 is a fluid pipe 220. The bottom portion of fluid pipe 220 has the capability of allowing a fluid 230 to flow to surface 206. At the end of fluid pipe 220 is an end of pipe assembly 225, which can be one or more downhole tools or an end cap assembly. Fluid 230 flows from a subterranean formation 235 through fractures 240 to wellbore 210.

Fluid 230 can flow to choke manifold system 270 that has a positive choke bean and an adjustable choke valve. The methods and processes described herein can be performed using choke manifold system 270 to improve the choke model by reducing the margin of error between the flow rate through the positive choke bean and the flow rate through the adjustable choke valve, where the choke model provides a recommended orifice size for the adjustable choke valve.

FIG. 3 is an illustration of a diagram of an example offshore system 300 with an electric submersible pump (ESP) assembly 320. ESP assembly 320 is placed downhole in a wellbore 310 below a body of water 340, such as an ocean or sea. Wellbore 310, protected by casing, screens, or other structures, is surrounded by subterranean formation 345. ESP assembly 320 can be used for onshore operations. ESP assembly 320 includes a well controller 307 (for example, to act as a speed and communications controller of ESP assembly 320), an ESP motor 314, and an ESP pump 324.

Well controller 307 is placed in a cabinet 306 inside a control room 304 on an offshore platform 305, such as an oil rig, above water surface 344. Well controller 307 is configured to adjust the operations of ESP motor 314 to improve well productivity. In the illustrated aspect, ESP motor 314 is a two-pole, three-phase squirrel cage induction motor that operates to turn ESP pump 324. ESP motor 314 is located near the bottom of ESP assembly 320, just above downhole sensors within wellbore 310. A power/communication cable 330 extends from well controller 307 to ESP motor 314. A fluid pipe 332 fluidly couples equipment located on offshore platform 305 and ESP pump 324.

In some aspects, ESP pump 324 can be a horizontal surface pump, a progressive cavity pump, a subsurface compressor system, or an electric submersible progressive cavity pump. A motor seal section and intake section may extend between ESP motor 314 and ESP pump 324. A riser 315 separates ESP assembly 320 from water 340 until sub-surface 342 is encountered, and a casing 316 can separate wellbore 310 from subterranean formation 345 at and below sub-surface 342. Perforations in casing 316 can allow the fluid of interest from subterranean formation 345 to enter wellbore 310.

Fluid in wellbore 310 can flow to the surface, such as through a choke manifold system 350. Choke manifold system 350 can be communicatively coupled to well controller 307. Well controller 307 can include a machine learning system and a choke model, and, using collected data, can provide a recommendation to choke manifold system 350 as to the position of the adjustable choke valve to calibrate the adjustable choke system with the positive choke bean system.

FIGS. 1 and 2 depict onshore operations. Those skilled in the art will understand that the disclosure is equally well suited for use in offshore operations, such as shown in FIG. 3. FIGS. 1 - 3 depict specific wellbore configurations, those skilled in the art will understand that the disclosure is equally well suited for use in wellbores having other orientations including vertical wellbores, horizontal wellbores, slanted wellbores, multilateral wellbores, and other wellbore types.

FIG. 4 is an illustration of a diagram of an example well system 400 with a choke manifold. Well system 400 demonstrates one type of surface well equipment that can be utilized to implement this disclosure. Well system 400 includes a surface tree 410, such as derrick 105 or surface well equipment 205. The hydrocarbon fluid then flows to a sand management system 415, a surface safety valve 420, and a choke manifold system 425. Other well site equipment is also shown in well system 400. A well site controller, or other computing system, can be communicatively coupled to choke manifold system 425 and provide for the implementation of one or more of the methods or processes described herein.

FIG. 5 is an illustration of a diagram of an example choke manifold 500 with a positive choke and an adjustable choke. Choke manifold 500 can be located at a surface location of a well site of a well that is ready to start hydrocarbon production. A pipe from the wellbore can lead into the upstream input end of a choke manifold system 510 allowing the hydrocarbon fluid to flow from the wellbore into choke manifold system 510. The fluid at the upstream end can be, for example, between 10,000 and 50,000 pounds per square inch (PSI), and other PSI values outside of this range can also be experienced. Isolation valves 515 can be used to direct the hydrocarbon fluid, e.g., hydrocarbon fluid flow path, to a positive choke manifold portion 520 or an adjustable choke manifold portion 530. The hydrocarbon fluid can flow out through the downstream end of choke manifold system 510. The fluid at the downstream end can be, for example, in the 1,000 s PSI range, and other PSI values outside of this range can also be experienced.

Positive choke manifold portion 520 can include a positive choke bean of a specific size that can restrict the flow of the hydrocarbon fluid, thereby allowing consistent measurement of factors of the fluid to generate a portion of the collected data. Adjustable choke manifold portion 530 can include a variable positionable choke allowing a variable choke orifice size for the fluid to flow through. Calibrating the variable orifice size to the choke bean size can be problematic depending on the fluid factors, geologic factors, and environmental factors that can cause calibration differences, e.g., calibration errors, from the manufacturer’s recommended setting for the variable orifice size.

In some aspects, choke manifold system 510 can have sensors to collect data about the hydrocarbon fluid, such as its pressure, temperature, composition, contaminants, GOR, and other factors. In some aspects, the sensors can collect data at the upstream end of choke manifold system 510. In some aspects, the sensors can collect data at the downstream end of choke manifold system 510. In some aspects, choke manifold system 510 can have a computing system capable of implementing a choke model or another algorithm to analyze the collected data and generate a recommended adjustment to the calibration of the adjustable choke valve position. In some aspects, isolation valves 515 can be automatically controlled by a computing system, such as when the well testing operations are implemented by a computing system. In some aspects, the adjustable choke valve position can be adjusted automatically without user interaction.

FIG. 6 is an illustration of a diagram of an example chart 600 showing an adjustable choke calibration. Chart 600 demonstrates part of the analysis conducted by the disclosed processes. Chart 600 has an x-axis 605 showing the choke size in 64ths of an inch. A y-axis 606 shows the adjustable choke valve position as a percent of open. In plot area of chart 600, a fixed choke bean 620 (shown in various sizes using triangles) shows the corrected calibration curve for a specific fluid.

Recommended valve position 630 (shown in various positions using circles) shows the manufacturer’s recommended position for the adjustable choke valve with respect to the fixed choke bean size. Manufacturer’s indicator plate 625 shows an example of how the adjustable choke valve position is recommended. Error gap 640 shows the difference in flow rates between fixed choke bean 620 flow rate and recommended valve position 630, such as a calibration error. Error gap 640 can be the margin of error between flow states as used in method 900 and method 1000. Sliding line 650 demonstrates that the adjustable choke valve position can be adjusted to match the physical choke bean size which provides for the calibration correct.

FIG. 7 is an illustration of a diagram of an example chart 700 demonstrating issues during choke changes. Chart 700 has an x-axis 705 showing the collection of the data over time. Y-axis 706 is the fluid pressure in PSI. Peaks 720 demonstrate that at a point where choke changes are made, the physical system experiences peaks of fluid pressure. This can cause equipment damage. Data cannot be reliably collected during the peak pressure intervals and should be delayed until the pressure returns to its normal curve.

FIG. 8 is an illustration of a diagram of an example chart 800 demonstrating a flow rate margin of error. Chart 800 has an x-axis 805 showing data collected over time as well as generated flow rates over time. Y-axis 806 varies as to the data plotted, such that an upstream pressure line 820 uses a relative PSI and a flow rate 870 uses a relative flow rate volume. Upstream pressure line 820 rises as the adjustable choke manifold portion is utilized, such as using a choke position 830 representing 32/64 inches.

As the fluid flow changes from the adjustable choke manifold portion to the positive choke manifold portion, upstream pressure line 820 drops as shown by line portion 835. Positive choke bean size 840 allows for a lower upstream pressure. As the fluid changes from the positive choke manifold portion back to the adjustable choke manifold portion, upstream pressure increases as shown by line portion 845. The differences shown by upstream pressure line 820 is shown by margin of error 860.

The pressure data, combined with zero or more other factors, can be used to generate flow states for the different manifolds. Flow rate 870 shows a flow rate point 874 for the physical choke manifold portion and a flow rate point 872 for the adjustable choke manifold portion. The difference between the flow rates is a margin of error. This margin of error can be used to further calibrate the adjustable choke valve relative to the physical choke bean, and the results can be used to update a choke model.

FIG. 9 is an illustration of a flow diagram of an example method to improve and utilize a choke model. Method 900 can be performed, for example, by users performing analysis operations of the optimal hydrocarbon flow rate. Method 900 can be performed during a well testing operation, a production flowback operation, a production cleanup operation, a hydrocarbon fluid change event, or a specified time.

Method 900 can be performed on a computing system, such as a well site controller, data center, cloud environment, edge computing system, server, laptop, mobile device, or other computing system capable of receiving the input data and input parameters, and capable of communicating with other computing systems, for example, choke modeler system 1100 of FIG. 11 or choke modeler controller 1200 of FIG. 12. Method 900 can be encapsulated in software code or in hardware, for example, an application, code library, dynamic link library, module, function, RAM, ROM, and other software and hardware implementations. The software can be stored in a file, database, or other computing system storage mechanism. Method 900 can be partially implemented in software and partially in hardware.

Method 900 can start at a step 905 when generating, training, or updating the choke model. Method 900 can start at a step 940 when well testing operations begin. Proceeding from step 905, method 900 continues to a step 910. In step 910, historical data can be collected. In some aspects, historical data can be data collected from the current wellbore, from other wellbores in the same reservoir, or from wellbores in other reservoirs. In some aspects, the historical data can be collected from lab testing, simulations, or adjustable choke manufacture’s data.

Proceeding to a step 915, the historical data can be used in a user supervised mode to update choke model 920. The historical data can combine geologic factors, such as downhole pressure, temperature, type of hydrocarbon, GOR, inclusion of solids or contaminants, with the adjustable choke valve position and positive choke bean size so that the adjustable choke and positive choke manifold portions produce similar results.

In some aspects, the user can be replaced with a machine learning system to improve the auto updateability of the choke model. In some aspects, a design of experiments technique can be used to update the choke model. In some aspects, a physics-based technique can be used to update the choke model. In some aspects, a reliability methodology can be used to update the choke model. In some aspects, a combination of algorithms and techniques can be utilized, and a statistical algorithm can be used to combine the results, such as an average, a mean, a median, a maximum, a minimum, or other statistical algorithms.

Choke model 920 can be stored in various mediums, such as a data storage, a database, a server, a cloud environment, an edge computing system, a data center, a server, a mobile device, a laptop, or other computer storage systems whether transient or non-transient. The choke model can be stored and accessed on a well site controller. After the available historical data has been processed through the choke model, method 900 ends at a step 995.

Proceeding from step 940, method 900 continues to a step 945. In step 945, a determination can be made as to the stage of the well testing operation. The stages or sequence of stages can vary with the type of well and type of operations being conducted. In some aspects, for example, for well testing, there can be three stages, such as (1) initial cleanup - clearing the wellbore of contaminants at the start of first-flow (e.g., perforation debris, drilling mud, post treatment proppant, reservoir debris, or other contaminants), (2) flow stabilization - incremental step-up, e.g., increased choke size, to increase well flow rate so as to achieve maximum stable flow, and (3) final flow period - flow period, that can often be extended, at a maximum stable flow rate. In some aspects, these stages can be followed by downhole or surface shut-in operations to perform reservoir analysis.

In some aspects, flow state determination can utilize input data such as choke size, flow rate, well head pressure, well head temperature, and other input data. In some aspects, the input data can include equipment line-up, e.g., Separator, SMS systems engaged or bypassed, or other equipment. For example, when SMS is engaged and the Separator is bypassed, this can indicate early stage initial cleanup.

In other aspects, example stages for production flowback can utilize a similar sequence. The initial cleanup and flow stabilization stage can be different in that this operation can follow a proppant fracture operations. The flowback control can be different, such as with a goal to slowly flow the well in increments at a minimum rate to slowly close the fracture downhole without producing additional proppant from the reservoir.

In a step 950, data can be collected during well operations. The data can be various factors, such as the current pressure, temperature, or GOR of the hydrocarbon fluid, the factors can be the solids or contaminants in the fluid, or a combination thereof. The data can be collected from the fluid as it flows in the surface pipes.

In some aspects, in a step 955, the collected data can be analyzed using the choke model. Using the collected data as inputs into the choke model, the choke model can provide a recommended adjustable choke valve position for the conditions detected using an analysis of the collected data. The choke model can utilize the type, the model, or manufacturer of the choke manifold as part of the input data. In some aspects, in step 955, the collected data can be analyzed using a design of experiments algorithm, a reliability methodology algorithm, a physics-based algorithm, a manufacturer’s recommendation, or another algorithm or model.

In a decision step 960, the confidence level of the recommendation can be evaluated. For example, the decision can compare the confidence level to a choke error threshold. This comparison can be of the margin of error calculated between the positive choke valve flow rate parameters and the adjustable choke valve flow rate parameters, such as using method 1000. If the choke error threshold is satisfied, then decision step 960 is ‘Yes’ and method 900 proceeds to a step 965. If the choke error threshold is not satisfied, then decision step 960 is ‘No’ and method 900 proceeds to a step 970.

In step 965, the recommendations from the choke model can be applied to the adjustable choke valve. In some aspects, the recommendation can be applied by a user. In some aspects, the recommendation can be applied automatically by a choke manifold system. Method 900 proceeds to a decision step 975.

In step 970, the recommendation is not applied to the adjustable choke valve. The system reverts to the last calibration setting. Method 900 proceeds along two paths. First, method 900 proceeds to step 910 where the collected data is used to update the choke model using the data collected at the well site. Second, method 900 proceeds to decision step 975.

In decision step 975, a determination can be made as to whether the well testing operations have completed. If the decision is ‘No’, then method 900 proceeds to step 950 where data collected at a subsequent time interval is used in the analysis. If the decision is ‘Yes’, then method 900 proceeds to step 995 and ends.

FIG. 10 is an illustration of a flow diagram of an example method to determine a margin of error between a positive choke bean and an adjustable choke valve. Method 1000 can be performed, for example, by users performing analysis operations of the optimal hydrocarbon flow rate. Method 1000 can be performed on a computing system, such as a well site controller, data center, cloud environment, edge computing system, server, laptop, mobile device, or other computing system capable of receiving the input data and input parameters, and capable of communicating with other computing systems, for example, choke modeler system 1100 of FIG. 11 or choke modeler controller 1200 of FIG. 12. Method 1000 can be encapsulated in software code or in hardware, for example, an application, code library, dynamic link library, module, function, RAM, ROM, and other software and hardware implementations. The software can be stored in a file, database, or other computing system storage mechanism. Method 1000 can be partially implemented in software and partially in hardware. Method 1000 can be encapsulated or partially encapsulated with one or more of the steps of method 900.

Method 1000 starts at a step 1005 and proceeds to a step 1010, where the fluid is analyzed through the adjustable choke valve, i.e., Flow State One. The adjustable choke valve position can be set to a manufacturer’s setting for a specified choke size or the position can be received from the choke model, using the initial data to determine the calibration setting. Some of the parameters collected can be collected at the upstream measuring point, e.g., prior to entering the adjustable choke portion of the choke manifold system, and some of the parameters collected can be collected at the downstream measuring point, e.g., after leaving the adjustable choke portion of the choke manifold system. The parameters, e.g., factors, can be, for example, pressure, temperature, GOR, flow velocity, solids rate, ρ (density), v (viscosity), or combinations thereof.

In a step 1015, the fluid flow is diverted from the adjustable choke valve to the positive choke valve, i.e., Flow State Two. An initial assumption is that the adjustable choke valve position will result in an equivalent flow state to the positive choke bean size. The same set of parameters, factors, can be collected. A margin of error one can be calculated such that margin of error one can be Flow State Two minus Flow State One. The Flow States One and Two are a combination of factors, and the margin of error represents the flow rate difference between the two flow states. The algorithm is represented by a minus operation and represents the compounded differences across each of the factors collected. Step 1010 and 1015 can be executed in various orders, such as performing step 1015 prior to step 1010.

In a step 1020, the adjustable choke valve position can be adjusted to compensate for margin of error One. In a step 1025, the fluid flow can be switched from the positive choke bean to the adjustable choke portion of the choke manifold system. This can be labeled as Flow State Three. A margin of error two can be calculated similarly to the margin of error one, e.g., Flow State Three minus Flow State Two, using the collected data. In a step 1030, the adjustable choke valve position can be modified to compensate for the margin of error two. The adjustable choke valve position adjustment and modification steps can reduce the margin of error below a choke error threshold.

In a decision step 1035, the process can determine if there are additional choke sizes in a set of designated choke sizes to test as part of the well testing operation plan. The set of designated choke sizes can include one or more choke sizes, and be in various sequences, such as increasing in size, or decreasing in size. If the decision resultant is ‘Yes’, method 1000 proceeds to a step 1040. If the decision resultant is ‘No’, method 1000 proceeds to a step 1045.

In step 1040, the adjustable choke valve position can be changed to the next designated choke size in the set of designated choke sizes. The next designated choke size can be greater or smaller. The process can determine that a step up or a step down in size is warranted in order to meet a target optimization. For example, the well testing operation plan can specify a change in valve size of 2/64 of an inch, 1/128 of an inch, 1/256 of an inch, 100 micrometers, or other size changes (using one of various measuring systems). The amount the adjustable choke valve position is changed can depend on the recommendation from the choke model. The recommendation may not follow a linear increment. The positive choke bean is also changed to the next size, which is typically a physical change to the positive choke body. Method 1000 proceeds to step 1010 to continue the analysis and testing.

In step 1045, the adjustments made to the adjustable choke valve position using the margin of error one and the margin of error two for each of the choke sizes can be used to update the choke model. Future iterations of this method 1000 or of method 900 can utilize the updated choke model to improve the accuracy of the adjustable choke valve position relative to a desired flow state for a specified choke size. Method 1000 proceeds to a step 1095 and ends.

With each iteration, e.g., choke size change, the choke model learns from previous margins of errors and self corrects, updating the choke model calibration parameters. The choke manifold system can utilize method 900 and method 1000 to automatically self-calibrate the adjustable choke valve position for each increment, such as using the data collected during the well testing operation, e.g., real-time or near real-time data.

With a choke model, each new well system can leverage the model as a starting point to begin the operation. A large error or disturbance in the early-stage choke changes can be avoided when beginning a well testing operation.

For potential features and predictor variables, the choke model can use incoming flow parameters, such as GOR, density, viscosity, solids content, data from a multi-phase flow meter, fluid velocity; geometric parameters, such as pipe size, amount of scale build up, amount of wear, roughness changes; environmental parameters, such as ambient temperature, current pressure and pressure rate changes and number of choke open/close cycles; and business consideration, such as lead time of replacement parts, cost of replacement parts; and operational concerns such as the field and basin, stage within the operation, which crew is operating the system, other well site factors and considerations, or a combination of these factors. Target optimizations can include oil output, gas output, water output, solids output, emissions output, equipment wear, other target optimizations, or combinations of optimizations. In some aspects, the positive choke bean portion of the choke manifold system can be eliminated thereby saving equipment cost, system downtime when changing the bean, and improve safety considerations at the well site.

FIG. 11 is an illustration of a block diagram of an example choke modeler system 1100, which can be implemented in one or more computing systems, for example, a well site controller, a data center, cloud environment, server, laptop, smartphone, tablet, and other computing systems. In some aspects, choke modeler system 1100 can be implemented using a choke modeler controller such as choke modeler controller 1200 of FIG. 12. Choke modeler system 1100 can implement one or more methods of this disclosure, such as method 900 of FIG. 9 and method 1000 of FIG. 10.

Choke modeler system 1100, or a portion thereof, can be implemented as an application, a code library, dynamic link library, function, module, other software implementation, or combinations thereof. In some aspects, choke modeler system 1100 can be implemented in hardware, such as a ROM, a graphics processing unit, or other hardware implementation. In some aspects, choke modeler system 1100 can be implemented partially as a software application and partially as a hardware implementation. Choke modeler system 1100 is a functional view of the disclosed processes and an implementation can combine or separate the described functions in one or more software or hardware systems.

Choke modeler system 1100 includes a data transceiver 1110, a choke model processor 1120, and a result transceiver 1130. The generated results and interim outputs from choke model processor 1120 can be communicated to a data receiver, such as one or more of a user 1160, a computing system 1162, or other processing or storage systems 1164. The generated results can be used to improve calibrations of an adjustable choke valve for a specified choke size parameter.

Data transceiver 1110 can receive input parameters, such as parameters to direct the operation of the analysis implemented by choke model processor 1120. The input parameters can be a specified algorithm to utilize, such as a machine learning algorithm, a design of experiments algorithm, a reliability method algorithm, or a physics-based algorithm. In input parameters can specify a statistical algorithm to utilize to combine more than one result, such as using a physics-based algorithm and a machine learning algorithm. Input parameters can be a geographic region, a subterranean formation parameter, a choke error threshold, a target optimization, a choke manifold manufacturer and model, a type of hydrocarbon fluid, or a pumped fluid composition. In some aspects, data transceiver 1110 can be part of choke model processor 1120.

Result transceiver 1130 can communicate one or more generated results, collected data, recommended choke size, and other parameters, to one or more data receivers, such as user 1160, computing system 1162, storage system 1164, or other well site related systems. For example, the recommended choke size can be communicated to the adjustable choke manifold portion to position the valve according to the choke model. Data transceiver 1110, choke model processor 1120, and result transceiver 1130 can be, or can include, conventional interfaces configured for transmitting and receiving data.

Choke model processor 1120 can implement the analysis and algorithms as described herein utilizing the collected data, the choke model, and the input parameters. For example, choke model processor 1120 can perform a recommendation process that uses the collected data to determine an adjustable choke valve position for the conditions being experienced by the fluid at the well site. Choke model processor 1120 can use one or more algorithms, such as machine learning, decision tree, random forest, logistic regression, linear, and other algorithms to determine the recommended choke size suing the choke model.

A memory or data storage of choke model processor 1120 can be configured to store the processes and algorithms for directing the operation of choke model processor 1120. Choke model processor 1120 can also include a processor that is configured to operate according to the analysis operations and algorithms disclosed herein, and an interface to communicate (transmit and receive) data.

FIG. 12 is an illustration of a block diagram of an example of choke modeler controller 1200 according to the principles of the disclosure. Choke modeler controller 1200 can be stored on a single computer or on multiple computers. The various components of choke modeler controller 1200 can communicate via wireless or wired conventional connections. A portion or a whole of choke modeler controller 1200 can be located at one or more locations, such as a well site controller, a reservoir controller, or other proximate or distance computing systems. In some aspects, choke modeler controller 1200 can be wholly located at a surface or distant location. In some aspects, choke modeler controller 1200 can be part of another system, and can be integrated in a single device. In some aspects, choke modeler controller 1200 can be part of a choke manifold.

Choke modeler controller 1200 can be configured to perform the various functions disclosed herein including receiving input parameters and generating results, e.g., recommendations of choke positions, from an execution of the methods and processes described herein. Choke modeler controller 1200 includes a communications interface 1210, a memory 1220, and a processor 1230.

Communications interface 1210 is configured to transmit and receive data. For example, communications interface 1210 can receive the input parameters, the collected data, and the choke model (or have access to the choke model). Communications interface 1210 can transmit the generated results, collected data, or interim outputs. In some aspects, communications interface 1210 can transmit a status, such as a success or failure indicator of choke modeler controller 1200 regarding receiving the various inputs, transmitting the generated results, or producing the generated results. In some aspects, communications interface 1210 can receive input parameters from a machine learning system, such as when the machine learning system uses the collected data as input and pre-processes the collected data, e.g., filters or transforms the collected data, prior to use by the choke model or other recommendation algorithm. In some aspects, the machine learning system can be implemented by processor 1230 and perform the operations as described by choke model processor 1120 of FIG. 11. Communications interface 1210 can communicate via communication systems used in the industry. For example, wireless or wired protocols can be used. Communication interface 1210 is capable of performing the operations as described for data transceiver 1110 and result transceiver 1130 of FIG. 11.

Memory 1220 can be configured to store a series of operating instructions that direct the operation of processor 1230 when initiated, including the code representing the algorithms for determining the matching analysis. Memory 1220 is a non-transitory computer readable medium. Multiple types of memory can be used for data storage and memory 1220 can be distributed.

Processor 1230 can be configured to produce the generated results, one or more interim outputs, and statuses utilizing the received inputs. For example, processor 1230 can perform an analysis of the collected data using one or more algorithms, such as the choke model, and generate a recommended valve position for an adjustable choke valve. Processor 1230 can be configured to direct the operation of the choke modeler controller 1200. Processor 1230 includes the logic to communicate with communications interface 1210 and memory 1220, and perform the functions described herein. Processor 1230 is capable of performing or directing the operations as described by choke model processor 1120 of FIG. 11.

A portion of the above-described apparatus, systems or methods may be embodied in or performed by various analog or digital data processors, wherein the processors are programmed or store executable programs of sequences of software instructions to perform one or more of the steps of the methods. A processor may be, for example, a programmable logic device such as a programmable array logic (PAL), a generic array logic (GAL), a field programmable gate arrays (FPGA), or another type of computer processing device (CPD). The software instructions of such programs may represent algorithms and be encoded in machine-executable form on non-transitory digital data storage media, e.g., magnetic or optical disks, random-access memory (RAM), magnetic hard disks, flash memories, and/or read-only memory (ROM), to enable various types of digital data processors or computers to perform one, multiple or all of the steps of one or more of the above-described methods, or functions, systems or apparatuses described herein.

Portions of disclosed examples or embodiments may relate to computer storage products with a non-transitory computer-readable medium that have program code thereon for performing various computer-implemented operations that embody a part of an apparatus, device or carry out the steps of a method set forth herein. Non-transitory used herein refers to all computer-readable media except for transitory, propagating signals. Examples of non-transitory computer-readable media include, but are not limited to: magnetic media such as hard disks, floppy disks, and magnetic tape; optical media such as CD-ROM disks; magneto-optical media such as floppy disks; and hardware devices that are specially configured to store and execute program code, such as ROM and RAM devices. Examples of program code include both machine code, such as produced by a compiler, and files containing higher level code that may be executed by the computer using an interpreter.

In interpreting the disclosure, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

Those skilled in the art to which this application relates will appreciate that other and further additions, deletions, substitutions and modifications may be made to the described embodiments. It is also to be understood that the terminology used herein is for the purpose of describing particular embodiments only, and is not intended to be limiting, since the scope of the present disclosure will be limited only by the claims. Unless defined otherwise, all technical and scientific terms used herein have the same meaning as commonly understood by one of ordinary skill in the art to which this disclosure belongs. Although any methods and materials similar or equivalent to those described herein can also be used in the practice or testing of the present disclosure, a limited number of the exemplary methods and materials are described herein.

Each of the aspects disclosed in SUMMARY section can have one or more of the following additional elements in combination. Element 1: further comprising analyzing the hydrocarbon fluid flowing through the adjustable choke manifold portion, utilizing the adjusted choke valve position, to generate a third flow state, wherein the positive choke manifold portion is isolated to direct the hydrocarbon fluid to the adjustable choke manifold portion. Element 2: further comprising modifying the adjustable choke position to compensate for a second margin of error, wherein the second margin of error is calculated utilizing the second flow state and the third flow state. Element 3: further comprising communicating the choke size, the first margin of error, or an amount of adjustment for the adjusting to one or more systems. Element 4: wherein the set of designated choke sizes includes more than one choke size in a sequence. Element 5: the method is executed for two or more choke sizes in the set of designated choke sizes. Element 6: where each execution of the method utilizes a next designated choke size in the set of designated choke sizes. Element 7: wherein the adjustable choke position is received from one or more of a choke model, a design of experiments algorithm, a reliability methodology algorithm, a physics-based algorithm, or a manufacturer’s recommendation. Element 8: wherein the one or more of the choke model, the design of experiments algorithm, or the physics-based algorithm are combined using a statistical algorithm. Element 9: where the statistical algorithm is one of an average, a mean, a median, a maximum, a minimum, a derivation of a highest efficiency, a derivation of a highest accuracy, a Bayesian optimization, an ensemble learning method, a stacked ensemble model, a weighted average, a method of quadrature, a Lagrange multiplier, or a derivative optimization. Element 10: wherein the choke model is updated using one or more of the first flow state, the second flow state, the first margin of error, or an amount of adjustment for the adjusting. Element 11: wherein the choke model is updated using historical data from one or more of the well site or other well sites. Element 12: wherein the first flow state and the second flow state utilize one or more factors of a GOR, a density, a viscosity, a pressure, a temperature, a solids content, or a data from a multi-phase flow meter. Element 13: where the one or more factors are collected at one or more of an upstream location or a downstream location, where the upstream location and downstream location are relative to the choke manifold. Element 14: wherein the method is performed during a well testing operation, a production flowback operation, a production cleanup operation, a hydrocarbon fluid change event, or a specified time. Element 15: wherein the adjusting is applied automatically by the adjustable choke manifold portion. Element 16: wherein the first flow state and the second flow state are generated utilizing a target optimization. Element 17: where the target optimization is one or more of minimized emissions, minimized solids, maximized gas output, maximized oil output, minimized water output, maximum flow rate while laminar, a pulsed flow, an equipment protection, or a balanced combination. Element 18: further comprising receiving the input parameters from one or more of equipment upstream of the choke manifold, equipment downstream of the choke manifold, or downhole the wellbore. Element 19: wherein the input parameters include one or more of a geographic region, a subterranean formation parameter, a choke error threshold, a statistical algorithm to utilize, a target optimization, an adjustable choke manifold manufacturer and model, a hydrocarbon fluid, or a pumped fluid composition. Element 20: wherein the choke manifold further includes one or more positive choke valves with a respective choke bean equivalent to the choke size. Element 21: wherein the collected data is received from one or more of an upstream location relative to the choke manifold or a downstream location relative to the choke manifold. Element 22: wherein the one or more adjustable choke valves utilize a PID control, a fractional order control, a feedforward compensation, a P control, a PI control, a PD control, a PIFF control, or predictive or rule based logic to maintain a respective adjustable choke position once an optimized position is determined. Element 23: further comprising a machine learning system, communicatively coupled to the choke model processor, and capable of identifying choke wear or impending choke failure of the choke manifold utilizing the collected data, generated flow states, and calculated margins of error, Element 24: wherein the generated flow states and calculated margins of error are generated by one or more of the machine learning system or the choke model processor. Element 25: further comprising a result transceiver, capable of communicating the recommended position, flow states, margins of errors, or interim outputs to a user, a data store, a computing system, a choke modeler system, or the choke manifold. Element 26: wherein the choke model processor utilizes a machine learning system or a deep learning neural network system to determine the recommended position. Element 27: wherein the choke model processor is communicatively coupled to the choke manifold. Element 28: the choke manifold automatically adjusts the one or more adjustable choke valves using the recommended position.

What is claimed is:

1. A method to reduce a calibration error for an adjustable choke valve of a choke manifold at a well site, comprising:
analyzing a hydrocarbon fluid flowing through a positive choke manifold portion of the choke manifold to generate a first flow state, wherein an adjustable choke manifold portion of the choke manifold is isolated to direct the hydrocarbon fluid to the positive choke manifold portion, the positive choke manifold portion utilizes a choke bean of an equivalent size to a choke size in a set of designated choke sizes, and the hydrocarbon fluid is flowing from a wellbore at the well site;
analyzing a hydrocarbon fluid flowing through the adjustable choke manifold portion utilizing input parameters to generate a second flow state, and the adjustable choke manifold portion has an adjustable choke position for the adjustable choke valve, where the adjustable choke position is equivalent to the choke size; and
adjusting the adjustable choke position to compensate for a first margin of error to determine an adjusted choke valve position, wherein the first margin of error is calculated utilizing the first flow state and the second flow state.

2. The method as recited in claim 1, further comprising:
analyzing the hydrocarbon fluid flowing through the adjustable choke manifold portion, utilizing the adjusted choke valve position, to generate a third flow state, wherein the positive choke manifold portion is isolated to direct the hydrocarbon fluid to the adjustable choke manifold portion; and
modifying the adjustable choke position to compensate for a second margin of error, wherein the second margin of error is calculated utilizing the second flow state and the third flow state.

3. The method as recited in claim 1, further comprising:
communicating the choke size, the first margin of error, or an amount of adjustment for the adjusting to one or more systems.

4. The method as recited in claim 1, wherein the set of designated choke sizes includes more than one choke size in a sequence, and the method is executed for two or more choke sizes in the set of designated choke sizes, where each execution of the method utilizes a next designated choke size in the set of designated choke sizes.

5. The method as recited in claim 1, wherein the adjustable choke position is received from one or more of a choke model, a design of experiments algorithm, a reliability methodology algorithm, a physics-based algorithm, or a manufacturer’s recommendation.

6. The method as recited in claim 5, wherein the one or more of the choke model, the design of experiments algorithm, or the physics-based algorithm are combined using a statistical algorithm, where the statistical algorithm is one of an average, a mean, a median, a maximum, a minimum, a derivation of a highest efficiency, a derivation of a highest accuracy, a Bayesian optimization, an ensemble learning method, a stacked ensemble model, a weighted average, a method of quadrature, a Lagrange multiplier, or a derivative optimization.

7. The method as recited in claim 5, wherein the choke model is updated using one or more of the first flow state, the second flow state, the first margin of error, or an amount of adjustment for the adjusting.

8. The method as recited in claim 5, wherein the choke model is updated using historical data from one or more of the well site or other well sites.

9. The method as recited in claim 1, wherein the first flow state and the second flow state utilize one or more factors of a gas to oil ratio (GOR), a density, a viscosity, a pressure, a temperature, a solids content, or a data from a multi-phase flow meter, where the one or more factors are collected at one or more of an upstream location or a downstream location, where the upstream location and downstream location are relative to the choke manifold.

10. The method as recited in claim 1, wherein the method is performed during a well testing operation, a production flowback operation, a production cleanup operation, a hydrocarbon fluid change event, or a specified time.

11. The method as recited in claim 1, wherein the adjusting is applied automatically by the adjustable choke manifold portion.

12. The method as recited in claim 1, wherein the first flow state and the second flow state are generated utilizing a target optimization, where the target optimization is one or more of minimized emissions, minimized solids, maximized gas output, maximized oil output, minimized water output, maximum flow rate while laminar, a pulsed flow, an equipment protection, or a balanced combination.

13. The method as recited in claim 1, further comprising:
receiving the input parameters from one or more of equipment upstream of the choke manifold, equipment downstream of the choke manifold, or downhole the wellbore.

14. The method as recited in claim 13, wherein the input parameters include one or more of a geographic region, a subterranean formation parameter, a choke error threshold, a statistical algorithm to utilize, a target optimization, an adjustable choke manifold manufacturer and model, a hydrocarbon fluid, or a pumped fluid composition.

15. A system, comprising:
a choke manifold having one or more adjustable choke valves, and capable of isolating each fluid flow path of the choke manifold, where the choke manifold is located at a well site of a hydrocarbon fluid producing wellbore; and
a choke model processor capable to receive collected data and generate a recommended position for the one or more adjustable choke valves using an equivalency of a choke size and the collected data.

16. The system as recited in claim 15, wherein the choke manifold further includes one or more positive choke valves with a respective choke bean equivalent to the choke size.

17. The system as recited in claim 15, wherein the collected data is received from one or more of an upstream location relative to the choke manifold or a downstream location relative to the choke manifold.

18. The system as recited in claim 15, wherein the one or more adjustable choke valves utilize a proportional integral derivative (PID) control, a fractional order control, a feedforward compensation, a proportional (P) control, a proportional integral (PI) control, a proportional derivative (PD) control, a Proportional Integral Feed Forward (PIFF) control, or predictive or rule based logic to maintain a respective adjustable choke position once an optimized position is determined.

19. The system as recited in claim 15, further comprising:
a machine learning system, communicatively coupled to the choke model processor, and capable of identifying choke wear or impending choke failure of the choke manifold utilizing the collected data, generated flow states, and calculated margins of error, wherein the generated flow states and calculated margins of error are generated by one or more of the machine learning system or the choke model processor.

20. The system as recited in claim 15, further comprising:
a result transceiver, capable of communicating the recommended position, flow states, margins of errors, or interim outputs to a user, a data store, a computing system, a choke modeler system, or the choke manifold.

21. The system as recited in claim 15, wherein the choke model processor utilizes a machine learning system or a deep learning neural network system to determine the recommended position.

22. The system as recited in claim 15, wherein the choke model processor is communicatively coupled to the choke manifold, and the choke manifold automatically adjusts the one or more adjustable choke valves using the recommended position.

23. A computer program product having a series of operating instructions stored on a non-transitory computer-readable medium that directs a data processing apparatus when executed thereby to perform operations to reduce a calibration error for an adjustable choke valve of a choke manifold at a well site, the operations comprising:
analyzing a hydrocarbon fluid flowing through a positive choke manifold portion of the choke manifold to generate a first flow state, wherein an adjustable choke manifold portion of the choke manifold is isolated to direct the hydrocarbon fluid to the positive choke manifold portion, the positive choke manifold portion utilizes a choke bean of an equivalent size to a choke size in a set of designated choke sizes, and the hydrocarbon fluid is flowing from a wellbore at the well site;
analyzing a hydrocarbon fluid flowing through the adjustable choke manifold portion utilizing input parameters to generate a second flow state, and the adjustable choke manifold portion has an adjustable choke position for the adjustable choke valve, where the adjustable choke position is equivalent to the choke size; and
adjusting the adjustable choke position to compensate for a first margin of error to determine an adjusted choke valve position, wherein the first margin of error is calculated utilizing the first flow state and the second flow state.
